(19) United States
(12) Patent Application Publication
(10) Pub. No.: US 2021/0119001 A1
(43) Pub. Date: Apr. 22, 2021

(54) SEMICONDUCTOR DEVICE AND MANUFACTURING METHOD OF THE SAME

(71) Applicant: DENSO CORPORATION, Kariya-city (JP)

(72) Inventors: EISUKE BANNO, Kariya-city (JP); SHUJI ASANO, Kariya-city (JP); SEIJI NOMA, Kariya-city (JP); SHINICHIRO UEYAMA, Kariya-city (JP)

(21) Appl. No.: 17/137,751

(22) Filed: Dec. 30, 2020

Related U.S. Application Data
(63) Continuation of application No. PCT/JP2019/025670, filed on Jun. 27, 2019.

(30) Foreign Application Priority Data
Jul. 2, 2018 (JP) 2018-126223

(51) Int. Cl. H01L 29/40; H01L 27/12; H01L 29/423; H01L 29/78; H01L 29/10; H01L 21/762

(52) U.S. Cl. CPC H01L 29/401; H01L 27/1207; H01L 29/423; H01L 21/31111; H01L 29/1087; H01L 21/76283; H01L 29/7816

(57) ABSTRACT

A semiconductor device includes: a semiconductor substrate including a support substrate, a buried insulating film, and an active layer stacked in the stated order; a trench isolation portion disposed in the active layer and dividing the active layer into a plurality of regions including an extracting region; and a contact electrode disposed in a through hole that is provided from a main surface of the semiconductor substrate to reach the support substrate in the extracting region, and electrically connected to the support substrate. A minimum width of a portion of the contact electrode being in contact with the support substrate is wider than a minimum width of a portion of the contact electrode located in the active layer.

### CROSS REFERENCE TO RELATED APPLICATIONS

The present application is a continuation application of International Patent Application No. PCT/JP2019/025670 filed on Jun. 27, 2019, which designated the U.S. and claims the benefit of priority from Japanese Patent Application No. 2018-126223 filed on Jul. 2, 2018. The entire disclosures of all of the above applications are incorporated herein by reference.

### TECHNICAL FIELD

The present disclosure relates to a semiconductor device and a manufacturing method of a semiconductor device.

### BACKGROUND

Conventionally, there has been known a semiconductor device configured by using a semiconductor substrate in which a support substrate, a buried insulating film, and an active layer are stacked in the stated order.

### SUMMARY

The present disclosure provides a semiconductor device and a manufacturing method of a semiconductor device. Each of the semiconductor devices includes: a semiconductor substrate including a support substrate, a buried insulating film, and an active layer stacked in the stated order; a trench isolation portion disposed in the active layer and dividing the active layer into a plurality of regions including an extracting region; and a contact electrode disposed in a through hole that is provided from a main surface of the semiconductor substrate to reach the support substrate in the extracting region, and electrically connected to the support substrate. A minimum width of a portion of the contact electrode being in contact with the support substrate is wider than a minimum width of a portion of the contact electrode located in the active layer.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional view of a semiconductor device according to a first embodiment;

FIG. 2 is a plan view of an extracting region shown in FIG. 1;

FIG. 3 is a schematic diagram showing a noise propagation path when a noise is generated in the semiconductor device shown in FIG. 1;

FIG. 4A is a sectional view illustrating a manufacturing process of the semiconductor device shown in FIG. 1;

FIG. 4B is a sectional view illustrating the manufacturing process of the semiconductor device subsequent to FIG. 4A;

FIG. 4C is a cross-sectional view illustrating a manufacturing process of the semiconductor device subsequent to FIG. 4B;

FIG. 4D is a cross-sectional view illustrating a manufacturing process of the semiconductor device subsequent to FIG. 4C;

FIG. 4E is a cross-sectional view illustrating a manufacturing process of the semiconductor device subsequent to FIG. 4D;

FIG. 4F is a cross-sectional view illustrating a manufacturing process of the semiconductor device subsequent to FIG. 4E;

FIG. 4G is a cross-sectional view illustrating a manufacturing process of the semiconductor device subsequent to FIG. 4F;

FIG. 4H is a cross-sectional view illustrating a manufacturing process of the semiconductor device subsequent to FIG. 4G;

FIG. 4I is a cross-sectional view illustrating a manufacturing process of the semiconductor device subsequent to FIG. 4H;

FIG. 5 is a diagram for explaining a subject that may arise when performing wet etching;

FIG. 6 is a diagram showing a relationship between an oxygen concentration of the support substrate and the amount of misalignment;

FIG. 7 is a schematic view showing a state of performing an abnormality determination of trench isolation portions in a wafer state in a case where a contact electrode is independent;

FIG. 8 is a schematic view showing a state of performing an abnormality determination of trench isolation portions in a wafer state in a case where a contact electrode is connected to a field region;

FIG. 9 is a cross-sectional view of a semiconductor device according to a second embodiment;

FIG. 10 is a plan view showing a positional relationship between an element region, trench isolation portions, and a contact electrode in the second embodiment;

FIG. 11 is a plan view showing a positional relationship between an element region, trench isolation portions, and contact electrodes in a third embodiment;

FIG. 12 is a diagram for explaining a noise propagation amount in the third embodiment;

FIG. 13 is a diagram showing a relationship between a distance between a first contact electrode and a second contact electrode, and a noise propagation amount and an area efficiency;

FIG. 14A is a plan view showing a positional relationship between an element region, trench isolation portions, and contact electrodes in another embodiment;

FIG. 14B is a plan view showing a positional relationship between an element region, trench isolation portions, and contact electrodes in another embodiment;

FIG. 15A is a plan view showing a positional relationship between an element region, trench isolation portions, and contact electrodes in another embodiment; and

FIG. 15B is a plan view showing a positional relationship between an element region, trench isolation portions, and contact electrodes in another embodiment.

### DETAILED DESCRIPTION

A semiconductor device according to a comparative example includes a semiconductor substrate in which a support substrate, a buried insulating film, and an active layer are stacked in the stated order. The active layer is divided into an element region and an extracting region by a trench isolation portion. In the element region, a switching element is formed by forming a P-type diffusion region, an N-type diffusion region, or the like. In the extracting region, a through hole penetrating through the active layer and the buried insulating film to reach the support substrate is provided, and a contact electrode electrically connected to the support substrate is disposed in the through hole. The through hole has a tubular shape in which a width between opposite sidewalls is substantially constant, and the contact electrode also has a columnar shape along the shape of the through hole. In such a semiconductor device, noise generated by switching on and off of the switching element formed in the element region may be propagated to the support substrate, but the noise propagated to the support substrate can be extracted by the contact electrode. Therefore, the propagation of noise to other regions of the active layer can be restricted.

However, in the above-described semiconductor device, it is desirable to more efficiently extract the noise propagated to the support substrate.

A semiconductor device according to an aspect of the present disclosure includes: a semiconductor substrate including a support substrate, a buried insulating film, and an active layer stacked in the stated order, and having a main surface that includes a surface of the active layer opposite from the buried insulating film; a trench isolation portion disposed in the active layer and dividing the active layer into a plurality of regions including an extracting region; and a contact electrode disposed in a through hole that is provided from the main surface of the semiconductor substrate to reach the support substrate in the extracting region, the contact electrode electrically connected to the support substrate. In one direction along a planar direction of the semiconductor substrate, a minimum width of a portion of the contact electrode being in contact with the support substrate is wider than a minimum width of a portion of the contact electrode located in the active layer, and a width of a portion of the contact electrode located adjacent to the main surface of the semiconductor substrate is wider than the minimum width of the portion of the contact electrode located in the active layer.

According to the above aspect, a contact area between the contact electrode and the support substrate can be increased and noise of the support substrate can be easily extracted as compared with a case where the minimum width of the contact electrode is constant at the minimum width of the portion located in the active layer.

According to another aspect of the present disclosure, a manufacturing method of a semiconductor device includes: preparing a semiconductor substrate in which a support substrate, a buried insulating film, and an active layer are stacked in the stated order, the semiconductor substrate having a main surface that includes a surface of the active layer opposite from the buried insulating film; forming a groove in the active layer to divide the active layer into a plurality of regions including an extracting region, and forming a through hole penetrating the active layer to reach the buried insulating film in the extracting region; disposing an insulating film in the groove and the through hole to form a trench isolation portion configured by the insulating film disposed in the groove;

exposing the support substrate from the through hole by removing the insulating film disposed in the through hole, removing the buried insulating film exposed from the though hole, and deepening the through hole; and forming a contact electrode electrically connected to the support substrate in the through hole. The exposing of the support substrate includes isotropically removing the buried insulating film by wet etching so that, in a distance between opposite sidewalls of the through hole, a minimum distance of a portion of the through hole exposing the support substrate is wider than a minimum distance of a portion of the through hole located in the active layer. The forming of the contact electrode includes forming the contact electrode so that a minimum width of a portion of the contact electrode being in contact with the support substrate is wider than a minimum width of a portion of the contact electrode located in the active layer, and a width of a portion of the contact electrode located adjacent to the main surface of the semiconductor substrate is wider than the minimum width of the portion of the contact electrode located in the active layer.

According to the above aspect, it is possible to manufacture a semiconductor device in which the minimum width of the portion of the contact electrode being in contact with the support substrate is wider than the minimum width of the portion located in the active layer. That is, it is possible to manufacture a semiconductor device in which a contact area between the contact electrode and the support substrate is increased to facilitate the extraction of noise from the support substrate.

The following describes embodiments of the present disclosure with reference to the drawings. In the following embodiments, the same or equivalent parts are denoted by the same reference numerals for description.

### First Embodiment

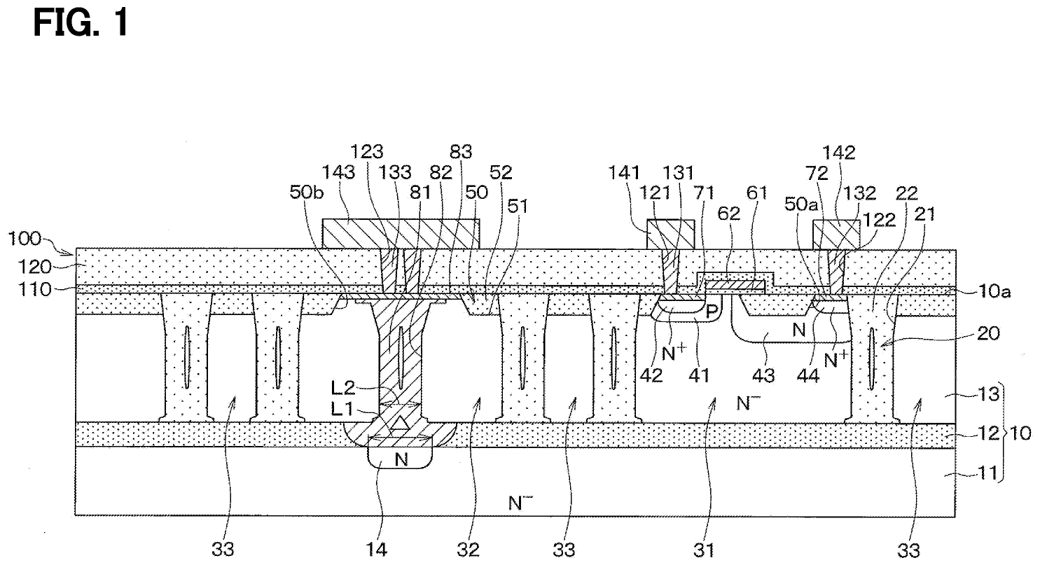

A first embodiment will be described with reference to the drawings. As shown in FIG. 1, a semiconductor device of the present embodiment is configured using a silicon on insulator (SOI) substrate 10 as a semiconductor substrate in which an active layer 13 is stacked above a support substrate 11 via a buried insulating film 12.

The support substrate 11 is made of an N⁻-type silicon substrate, for example. In the present embodiment, the support substrate 11 has an oxygen concentration of 1.27×10¹⁸ atoms/cm³ to 1.69×10¹⁸ atoms/cm³. The buried insulating film 12 is made of an oxide film or the like, and has a thickness of about several pm in order to maintain an insulating property between the support substrate 11 and the active layer 13. In the present embodiment, the active layer 13 is formed into an N⁻-type by ion-implanting an N-type impurity such as phosphorus into a P-type semiconductor layer and heat-treating the semiconductor layer. Hereinafter, a surface of the SOI substrate 10 including a surface of the active layer 13 opposite from the buried insulating film 12 is referred to as a main surface 10a of the SOI substrate 10.

The active layer 13 is divided by a trench isolation portion 20 into an element region 31, an extracting region 32, and a field region 33. In the present embodiment, the active layer 13 is divided by the trench isolation portion 20 so that the field region 33 is disposed between the element region 31 and the extracting region 32. In the present embodiment, multiple field regions 33 are formed, and the field region 33 is also formed on an opposite side from the element region 31 with the extracting region 32 interposed therebetween.

The trench isolation portion 20 includes a groove 21 and an insulating film 22. The groove 21 is formed from the main surface 10a of the SOI substrate 10 to reach the buried insulating film 12, and the groove 21 is filled with the insulating film 22. As will be described later, the insulating film 22 is formed by filling the groove 21 with an insulating material by deposition or the like.

In the present embodiment, a switching element is formed in the element region 31 using a diffusion region formed by diffusing impurities. Specifically, in the element region 31, a p-type body region 41 having a higher impurity concentration than the active layer 13 is formed in a surface layer portion of the active layer 13. In a surface layer portion of the body region 41, an N⁺-type source region 42 is formed.

Further, in the element region 31, an N-type drift region 43 is formed in a surface layer portion of the active layer 13 at a position away from the body region 41. In a surface layer portion of the drift region 43, an N⁺-type drain region 44 having a higher impurity concentration than the drift region 43 is formed.

Further, a shallow trench isolation (STI) separating portion 50 is formed in a surface layer portion of the element region 31. The STI separating portion 50 is formed in such a manner that after a trench 51 having a predetermined depth is provided in the surface layer portion of the active layer 13 and the trench 51 is filled with an insulating film 52, the insulating film 52 is planarized by a chemical mechanical polishing (CMP) method or the like. The STI separating portion 50 is also formed in the extracting region 32 and the field region 33.

In the element region 31, the STI separating portion 50 has an opening 50a so that the body region 41, the source region 42, the drift region 43, and the drain region 44 are exposed. In addition, in the extracting region 32, the STI separating portion 50 has an opening 50b so that a contact electrode 81 described later is exposed. The STI separating portion 50 also has an opening in a cross section different from FIG. 1 so that a part of the field region 33 is exposed.

Above the main surface 10a of the SOI substrate 10 in the element region 31, a gate electrode 62 is disposed via a gate insulating film 61. The gate insulating film 61 is formed from a position above a part of the STI separating portion 50 adjacent to the body region 41 to a position above the body region 41, and the gate electrode 62 is disposed above the gate insulating film 61.

Further, in the element region 31, silicide layers 71, 72 are formed at positions connected with first and second connecting vias 131, 132 for reducing the contact resistance with the first and second connecting vias 131, 132. In the present embodiment, the silicide layer 71 is formed on the source region 42, and the silicide layer 72 is formed on the drain region 44. Each of the silicide layers 71 and 72 is made of, for example, cobalt silicon (CoSi).

In the present embodiment, an N-channel metal-oxide-semiconductor field-effect transistor (MOSFET) element is formed in the element region 31 as described above. The MOSFET element formed in the element region 31 in the present embodiment is used by frequently switching between an on state in which a current flows and an off state in which a current does not flow by switching a voltage applied to the gate electrode 62. Therefore, noise may be generated in the MOSFET element. That is, in the present embodiment, it can be said that a noise generating element in which noise may be generated is formed in the element region 31.

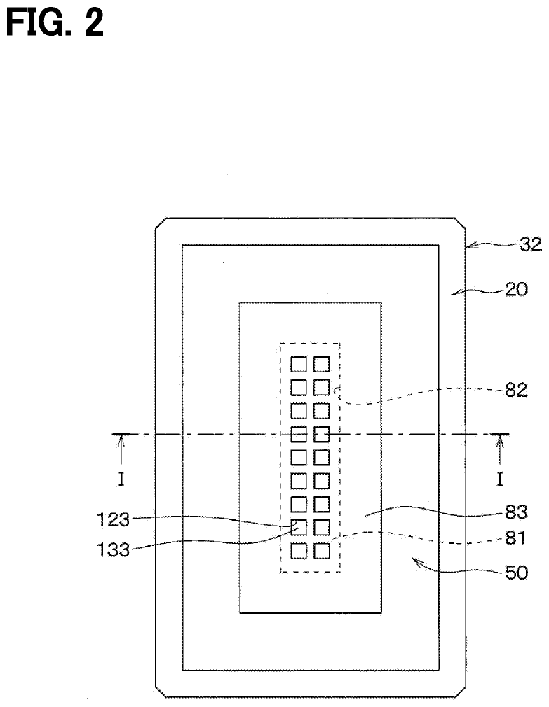

As shown in FIGS. 1 and 2, a contact electrode 81 electrically connected to the support substrate 11 is disposed in the extracting region 32. Specifically, the extracting region 32 has a through hole 82 that penetrates the buried insulating film 12 from the main surface 10a of the SOI substrate 10 and reaches the support substrate 11. The contact electrode 81 is disposed in the through hole 82 so as to be electrically connected to the support substrate 11. Note that FIG. 2 is a plan view of the extracting region 32 of FIG. 1, but a third wiring portion 143, an interlayer insulating film 120, and a surface insulating film 110, which will be described later, are omitted. Further, the extracting region 32 in FIG. 1 corresponds to a cross section taken along the line I-I in FIG. 1.

In the present embodiment, the through hole 82 has a rectangular opening as shown in FIG. 2. Further, as shown in FIG. 1, in the distance between opposite sidewalls of the through hole 82, a first minimum distance L1 of a portion where the support substrate 11 is exposed is wider than a second minimum distance L2 of a portion located in the active layer 13. The contact electrode 81 is disposed so as to fill the through hole 82.

Therefore, assuming that the length of the contact electrode 81 in one direction along a surface direction (i.e., planar direction) of the SOI substrate 10 is the width, the minimum width (hereinafter referred to as the first minimum width) L1 of the portion connected to the support substrate 11 is wider than the minimum width (hereinafter referred to as the second minimum width) L2 of the portion located in the active layer 13. Although not particularly limited, for example, the first minimum width L1 is about 2.9 μm, and the second minimum width L2 is about 1.2 μm. Since the contact electrode 81 is disposed so as to fill the through hole 82, the first minimum width L1 is equal to the first minimum distance L1 of the through hole 82, and the second minimum width L2 is equal to the second minimum distance L2.

Further, in the present embodiment, as will be described later, the contact electrode 81 is formed by filling the through hole 82 with a doped-polysilicon. Therefore, in order to improve the filling property of the doped-polysilicon, a minimum width of a portion of the through hole 82 that opens the main surface 10a, that is, a minimum width of a portion the through hole 32 located adjacent to the through hole 82 is also wider than the second minimum width L2. The contact electrode 81 is also disposed so as to fill a portion of the through hole 82 located adjacent to the main surface 10a. Therefore, it can be said that the contact electrode 81 of the present embodiment has a substantially I-shaped cross section.

Further, the contact electrode 81 is made of N-type polysilicon doped with phosphorus or the like so as to match the conductive-type of the support substrate 11. As a result, the contact electrode 81 and the support substrate 11 can form an ohmic contact.

Further, in the support substrate 11, an N-type exuding layer 14 is formed at a portion connected to the contact electrode 81. As will be described later, when the contact electrode 81 is disposed in the through hole 82, and then a heat treatment is performed to form the source region 42, the drain region 44, and the like in the element region 31, phosphorous contained in the contact electrode 81 exudes into the support substrate 11, thereby forming the exuding layer 14. That is, the exuding layer 14 of the present embodiment is formed without any special treatment for forming the exuding layer 14.

Further, in the extracting region 32, a silicide layer 83 is formed in a portion connected to a third connecting via 133 so as to reduce the contact resistance with the third connecting via 133. The silicide layer 83 is made of, for example, cobalt silicon, like the silicide layers 71 and 72 formed in the element region 31.

On the main surface 10a of the SOI substrate 10, a wiring layer 100 is formed. In the present embodiment, the surface insulating film 110 is formed on the main surface 10a, and the interlayer insulating film 120 is formed on the surface insulating film 110. The surface insulating film 110 is formed so as to cover the gate insulating film 61 and the gate electrode 62.

The interlayer insulating film 120 and the surface insulating film 110 have a first contact hole 121 that exposes the silicide layer 71 on the source region 42 and a second contact hole 122 that exposes the silicide layer 72 on the drain region 44. Further, the interlayer insulating film 120 and the surface insulating film 110 have a third contact hole 123 that exposes the silicide layer 83 on the contact electrode 81. The first to third contact holes 121 to 123 are filled with tungsten, thereby forming first to third connecting vias 131 to 133 electrically connected to the silicide layers 71, 72, and 83, respectively.

In the present embodiment, multiple third contact holes 123 are provided so as to expose multiple portions of contact electrodes 81 as shown in FIGS. 1 and 2.

Specifically, multiple third contact holes 123 are provided in two rows along one direction of the main surface 10a. The third connecting via 133 is disposed in each of the third contact holes 123.

In a cross section different from that of FIG. 1, a fourth contact hole for exposing the field region 33 is provided in the interlayer insulating film 120 and the surface insulating film 110. Then, the fourth contact hole is filled with tungsten, thereby forming a fourth connecting via.

On the interlayer insulating film 120, first to third wiring portions 141 to 143 made of aluminum or the like are formed so as to be connected to the first to third connecting vias 131 to 133, respectively. The third wiring portion 143 is formed so as to be connected to each of the third connecting via 133.

Further, in the present embodiment, the third wiring portion 143 is connected to the contact electrode 81 via the third connecting via 133, but is formed so as not to be electrically connected to other wiring portions or other regions. That is, the third wiring portion 143 is a wiring portion connected only to the contact electrode 81, and is an independent wiring. Therefore, the contact electrode 81 is not connected to other regions.

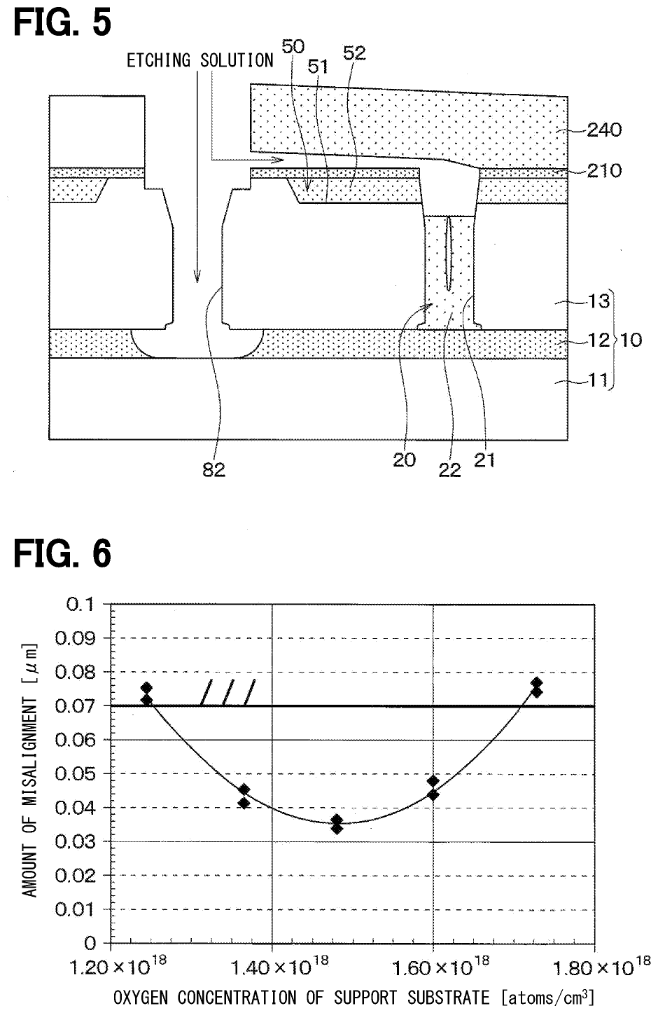

Each of the field regions 33 is electrically connected to a fourth wiring portion formed on the interlayer insulating film 120 via a fourth connecting via in a cross section different from FIG. 1. Further, the field regions 33 are electrically connected to each other through fourth wiring portions 144, respectively, as shown in FIG. 7 described later.

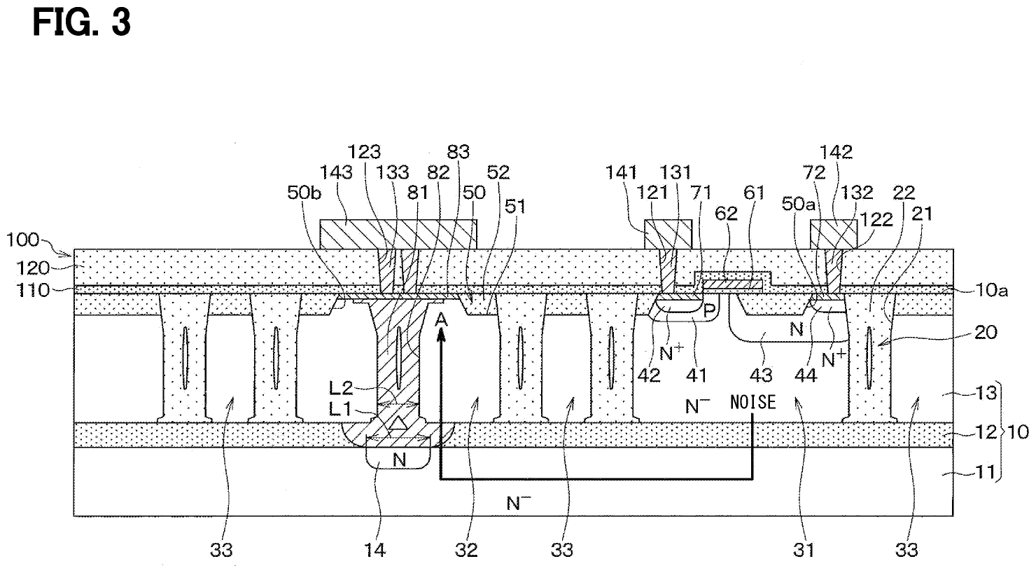

The configuration of the semiconductor device according to the present embodiment has been described above. In such a semiconductor device, as shown in FIG. 3, a noise may be generated from the MOSFET element formed in the element region 31, and the noise may be propagated to the support substrate 11. In this case, the noise propagated to the support substrate 11 is extracted by the contact electrode 81 as shown by the arrow A in FIG. 3, so that the noise can be restricted from being propagated to other regions.

In the present embodiment, the first minimum width L1 of the contact electrode 81 is wider than the second minimum width L2 of the contact electrode 81. Therefore, compared with a case where the first minimum width L1 and the second minimum width L2 of the contact electrode 81 are equal to each other, the contact area between the contact electrode 81 and the support substrate 11 can be increased and the noise of the support substrate 11 can be easily extracted.

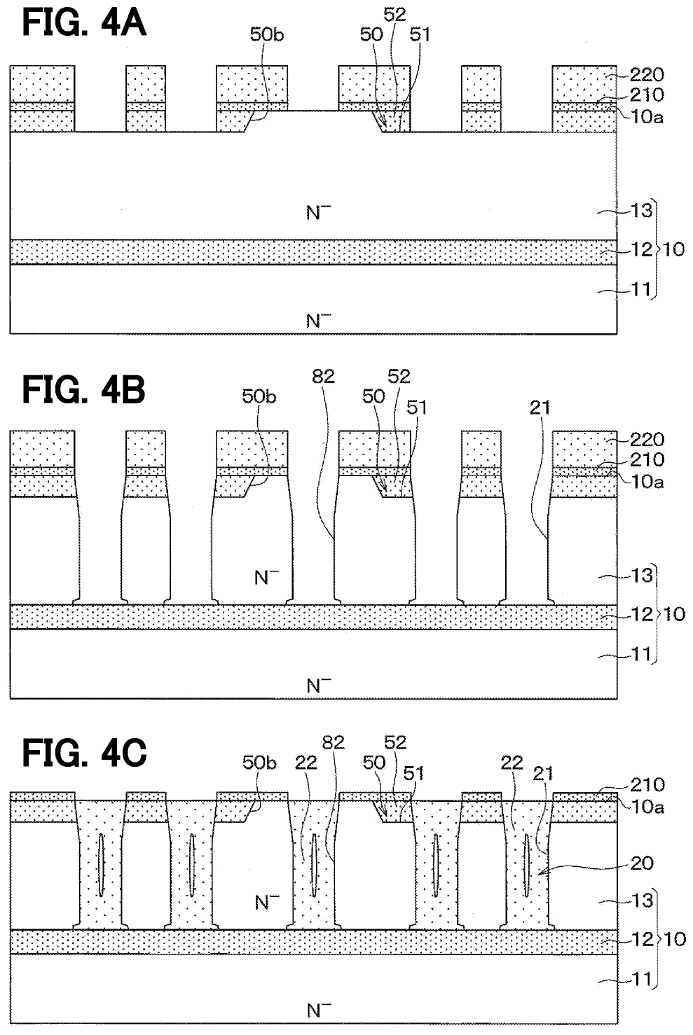

Next, a manufacturing method of the semiconductor device will be described with reference to FIGS. 4A to 4I. Since the manufacturing method of the MOSFET element formed in the element region 31 is the same as the conventional method, a manufacturing method of the contact electrode 81 formed in the extracting region 32 will be mainly described below. Further, in the present embodiment, the following steps are performed in a wafer state in which different chip regions are arranged so as to sandwich a scribe region, and the same steps are simultaneously performed for each of the chip regions.

First, as shown in FIG. 4A, a wafer-shaped SOI substrate 10 in which the STI separating portion 50 is formed in the surface layer portion of the active layer 13 is prepared. Next, a hard mask is formed on the main surface 10a by forming a nitride film 210 and an oxide film 220 in order by a chemical vapor deposition (CVD) method or the like. Then, the hard mask is patterned so as to expose regions where the groove 21 and the through hole 82 are to be formed.

Next, as shown in FIG. 4B, the groove 21 and the through hole 82 are formed at the same time by performing dry etching.

Subsequently, as shown in FIG. 4C, the groove 21 and the through hole 82 are filled with the insulating film 22 such as an oxide film. Accordingly, the insulating film 22 is disposed in the groove 21 to form the trench isolation portion 20. When filling with the insulating film 22, for example, the insulating film is deposited so as to fill up to the middle portion of the groove 21 and the through hole 82, and after etching back, the deposition is performed again. After that, tetraethyl orthosilicate (TEOS) or the like is formed by a CVD method or the like so as to close portions of the groove 21 and the through hole 82 adjacent to the main surface 10a. As a result, it is possible to restrict the occurrence of an issue that the insulating film 22 is not disposed in a portion of the groove 21 adjacent to the opening. Then, the oxide film 220 is removed by a CMP method or the like.

Next, as shown in FIG. 4D, a nitride film 230 is formed again by a CVD method or the like. Accordingly, the groove 21 and the through hole 82 are closed by the nitride film 230. That is, in the trench isolation portion 20, the nitride film 230 is disposed on the insulating film 22.

Subsequently, as shown in FIG. 4E, a photoresist 240 is disposed on the nitride film 230, and the photoresist 240 is patterned so as to expose a portion of the nitride film 230 that closes the through hole 82. Then, using the photoresist 240 as a mask, dry etching is performed so that the width of the portion of the through hole 82 adjacent to the opening is widened. At this time, the insulating film 22 disposed in the portion of the through hole 82 adjacent to the opening is also removed.

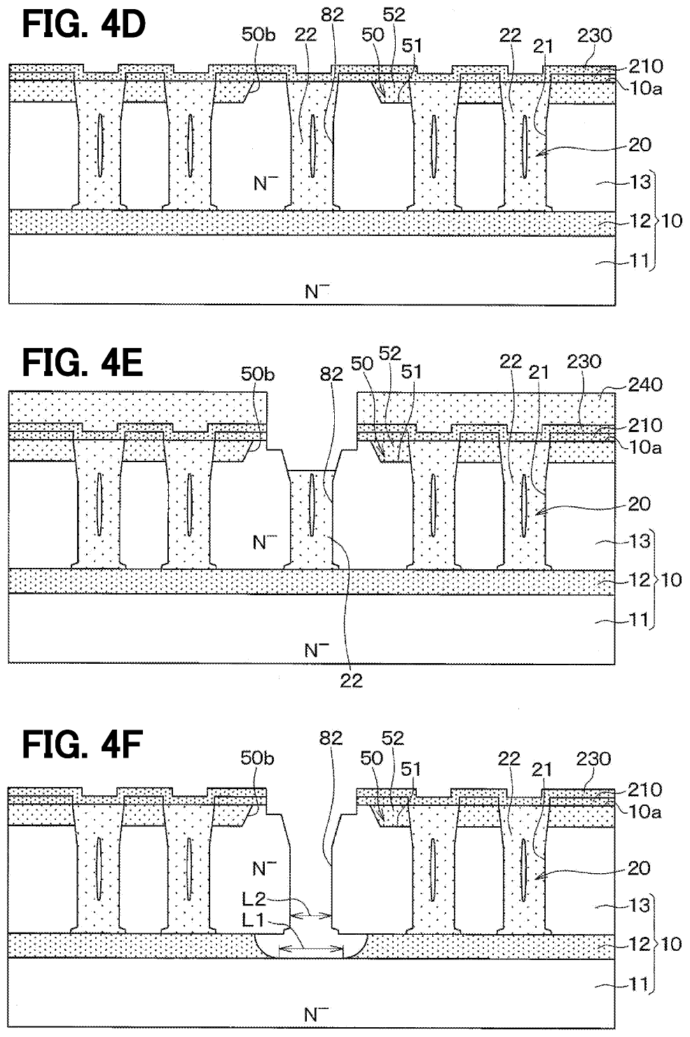

Next, as shown in FIG. 4F, the insulating film 22 formed in the through hole 82 and the buried insulating film 12 exposed from the through hole 82 are removed by performing wet etching. At this time, since wet etching is performed, the buried insulating film 12 is isotropically removed. Therefore, in the distance between the opposite sidewalls of the through hole 82, the first minimum distance L1 of the portion where the support substrate 11 is exposed is wider than the second minimum distance L2 of the portion located in the active layer 13. When performing wet etching, buffered hydrofluoric acid or the like can be used as an etching solution. In the present embodiment, since the nitride film 230 is disposed so as to close the opening of the groove 21 in the process of FIG. 4D, the insulating film 22 of the trench isolation portion 20 is restricted from being removed. That is, as shown in FIG. 5, since the nitride film 210 and the photoresist 240 have low adhesion, the photoresist 240 may be peeled off from the nitride film 210 and a gap may be generated between the photoresist 240 and the nitride film 210 during wet etching. In this case, if the nitride film 230 is not formed, the etching solution may enter from the opening of the groove 21 through the gap and the insulating film 22 may be removed. If the insulating film 22 is removed, issues such as a decrease in the withstand voltage of the trench isolation portion 20 and a decrease in the flatness of the wiring layer 100 may occur.

On the other hand, in the present embodiment, the opening of the groove 21 is closed by the nitride film 230. Therefore, even if a gap is generated between the photoresist 240 and the nitride film 230, the insulating film 22 constituting the trench isolation portion 20 can be restricted from being removed.

Subsequently, as shown in FIG. 4G, a doped-polysilicon doped with phosphorous or the like is formed to fill the through hole 82 by a CVD method or the like, thereby forming the contact electrode 81.

Next, as shown in FIG. 4H, the doped-polysilicon and the nitride films 210 and 230 formed on the main surface 10a are removed by a CMP method or the like. After that, impurities are appropriately ion-implanted into the element region 31, and then heat treatment is performed multiple times to form the body region 41, the source region 42, the drift region 43, and the drain region 44. The heat treatment is performed multiple times by appropriately setting the temperature, but in the present embodiment, the highest heat treatment temperature is set to about 1100° C. At this time, as shown in FIG. 41, since phosphorus in the doped polysilicon constituting the contact electrode 81 exudes to the support substrate 11 by the heat treatment, the exuding layer 14 is formed on the support substrate 11. That is, in the present embodiment, the exuding layer 14 is formed in the same step as the step of forming the body region 41, the source region 42, the drift region 43, and the drain region 44 in the element region 31. Therefore, no special step for forming the exuding layer 14 is performed.

When the heat treatment is performed, the support substrate 11 is fixed to the heating furnace, but if dislocations as defects occur in the support substrate 11, the support substrate 11 may warp. If the support substrate 11 warps, the source region 42 and the drain region 44 formed in the element region 31 will be misaligned, and the characteristics of the semiconductor device will change.

Specifically, if the oxygen concentration of the support substrate 11 is too low, the number of oxygen atoms that restrict the extension of the generated dislocations is reduced, so that the dislocations easily extend and the support substrate 11 easily warps. Further, if the oxygen concentration of the support substrate 11 is too high, dislocations are likely to occur due to oxygen atoms, and the support substrate 11 easily warps. That is, in order to restrict the warp of the support substrate 11, it is preferable to set the oxygen concentration appropriately.

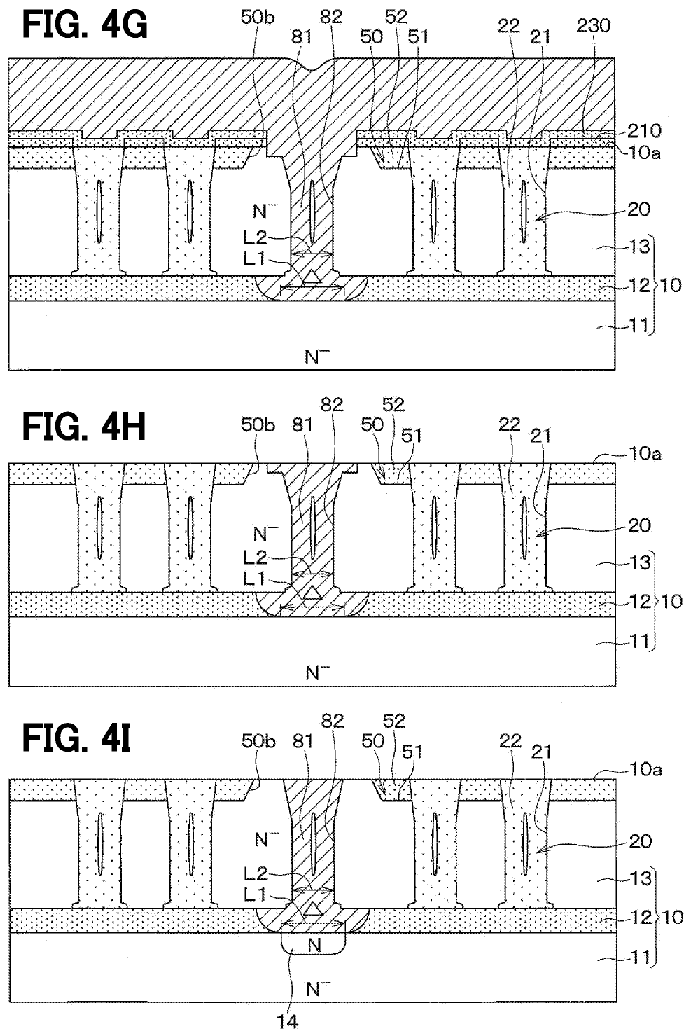

Therefore, the present inventors conducted an experiment on the oxygen concentration of the support substrate 11 and the amount of misalignment of the source region 42, the drain region 44, and the like in the element region 31, and obtained the results shown in FIG. 6. As shown in FIG. 6, the amount of misalignment is the smallest when the oxygen concentration of the support substrate 11 is 1.475×10¹⁸ atoms/cm³. The amount of misalignment increases as the oxygen concentration of the support substrate 11 becomes lower than 1.475×10¹⁸ atoms/cm³. Further, the amount of misalignment increases as the oxygen concentration of the support substrate 11 becomes higher than 1.475×10¹⁸ atoms/cm³. At present, the amount of misalignment is generally demanded to be suppressed to 0.07 μm or less. Therefore, in the present embodiment, the oxygen concentration of the support substrate 11 is 1.27×10¹⁸ atoms/cm³ to 1.69×10¹⁸ atoms/cm³. Accordingly, it is possible to restrict an increase in the amount of misalignment when the source region 42 and the drain region 44 are formed in the element region 31, and it is possible to restrict a change in the characteristics of the semiconductor device.

After that, although not particularly shown, the silicide layers 71 and 72 are formed in the element region 31, and the silicide layer 83 is formed in the extracting region 32, and then the surface insulating film 110 and the interlayer insulating film 120 are formed in order. Then, the first to third contact holes 121 to 123 and the like penetrating the interlayer insulating film 120 and the surface insulating film 110 are formed, and the first to third contact holes 121 to 123 are filled with tungsten to form the first to third connecting vias 131 to 133 and the like. Subsequently, after forming a metal layer made of aluminum on the interlayer insulating film 120, the metal layer is patterned to form the first to third wiring portions 141 to 143 and the like.

In the process of forming the first to third contact holes 121 to 123, the first to third connecting vias 131 to 133, and the first to third wiring portions 141 to 143, the fourth contact hole, the fourth connecting via, and the fourth wiring portion are also formed.

Further, in the present embodiment, the above steps are performed in the wafer state. Therefore, in the steps of forming the first to third contact holes 121 to 123, the first to third connecting vias 131 to 133, and the first to third wiring portions 141 to 143, a fifth contact hole that exposes the scribe region, a fifth connecting via disposed in the fifth contact hole, and a fifth wiring portion electrically connected to the fifth connecting via are also formed. The fifth contact hole that exposes the scribe region, the fifth connecting via that is disposed in the fifth contact hole, and the fifth wiring portion electrically connected to the fifth connecting via will be described later.

Next, in the present embodiment, an abnormality determination of the trench isolation portions 20 is performed. In the present embodiment, the above steps are performed in the wafer state, and the following will describe an example in which a first chip region 310 and a second chip region 320 are arranged with a scribe region 300 interposed therebetween as shown in FIG. 7. That is, the following will describe an example in which the abnormality determination of the trench isolation portions 20 in the first chip region 310 and the second chip region 320 is performed in the wafer state.

In the present embodiment, as shown in FIG. 7, the abnormality determination of the trench isolation portions 20 is performed by connecting an inspection device 400 to each of the wiring portions 141 to 145, and determining whether electric currents flow between power sources 411, 421 and grounds 421, 422 in the inspection device 400.

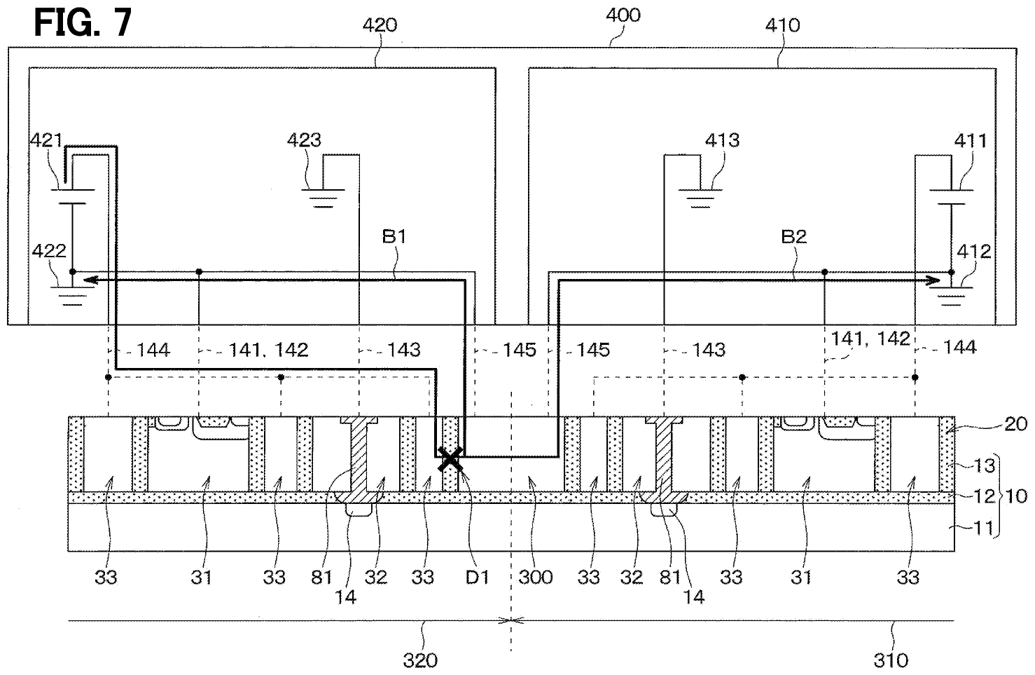

FIGS. 7 and 8 are schematic views showing the connection state of the inspection device 400 and the respective regions 31 to 33, and the first to fifth wiring portions 141 to 145 in the wiring layer 100 are simply shown by dotted lines. Further, the fourth wiring portion 144 in FIGS. 7 and 8 is a wiring portion connected to each of the field regions 33. The fifth wiring portion 145 in FIGS. 7 and 8 is a wiring portion connected to the scribe region 300 through the fifth connecting via disposed in the fifth contact hole formed in the interlayer insulating film 120 and the surface insulating film 110.

In the present embodiment, the inspection device 400 has a first inspection unit 410 and a second inspection unit 420, the first inspection unit 410 is connected to the first chip region 310, and the second inspection unit 420 is connected to the second chip region 320. Specifically, the power source 411 of the first inspection unit 410 is connected to the fourth wiring portion 144 connected to the field region 33. The ground 412 of the first inspection unit 410 is connected to the first and second wiring portions 141 and 142 connected to the element region 31, and is connected to the fifth wiring portion 145 connected to the scribe region 300. The ground 413 of the first inspection unit 410 is connected only to the third wiring portion 143 connected to the contact electrode 81. That is, in the present embodiment, the contact electrode 81 of the first chip region 310 is independently connected to the ground 413 of the first inspection unit 410.

Similarly, the power source 421 of the second inspection unit 420 is connected to the fourth wiring portion 144 connected to the field region 33. The ground 422 of the second inspection unit 420 is connected to the first and second wiring portions 141 and 142 connected to the element region 31, and is connected to the fifth wiring portion 145 connected to the scribe region 300. The ground 423 of the second inspection unit 420 is connected only to the third wiring portion 143 connected to the contact electrode 81. That is, in the present embodiment, the contact electrode 81 of the second chip region 320 is independently connected to the ground 423 of the second inspection unit 420.

Then, the inspection device 400 determines whether an electric current flows through the first chip region 310 and the second chip region 320 in order, so as to determine whether an abnormality occurs in the trench isolation portions 20 of the first chip region 310 and the trench isolation portion 20 in the second chip region 320.

Here, in the present embodiment, the contact electrode 81 is not connected to the field region 33 and is independent. However, if the contact electrode 81 is connected to the field region 33, the following issue may occur.

As shown in FIG. 8, when the contact electrode 81 is connected to the field region 33, for example, in the first chip region 310, the contact electrode 81 is also connected to the power source 411. In this case, since the contact electrodes 81 of the chip regions 310 and 320 are connected to the support substrate 11, the contact electrodes 81 are electrically connected to each other through the support substrate 11. For example, it is assumed that an abnormality D2 occurs in the trench isolation portion 20 that divides the scribe region 300 and the field region 33 in the second chip region 320.

In this case, when the abnormality determination of the trench isolation portion 20 in the first chip region 310 is performed, an electric current flows in a path indicated by the arrow C in FIG. 8 even though there is no abnormality in the trench isolation portions 20 of the first chip region 310. Therefore, the first inspection unit 410 erroneously determines that an abnormality occurs in the trench isolation portions 20 of the first chip region 310 even though there is no abnormality in the trench isolation portions 20 of the first chip region 310.

On the other hand, in the present embodiment, the contact electrode 81 is not connected to the field region 33. Therefore, for example, as shown in FIG. 7, if an abnormality D1 occurs in the trench isolation portion 20 that divides the scribe region 300 and the field region 33 in the second chip region 320, the following occurs. That is, when the abnormality determination of the first chip region 310 is performed, since the contact electrode 81 is independent, no electric current flows through the first inspection unit 410. Then, when the abnormality determination of the second chip region 320 is performed, an electric current flows through the second inspection unit 420 as shown by the arrow B1 in FIG. 7. When the abnormality determination of the second chip region 320 is performed, an electric current also flows to the ground 412 of the first inspection unit 410 as shown by the arrow B2 in FIG. 7. However, there is no particular problem even if an electric current flows to the ground 412 of the first inspection unit 410 during the abnormality determination of the second chip region 320.

In the present embodiment, the abnormality determination of the trench isolation portion 20 is performed in this way. Therefore, it is possible to prevent erroneous determination when performing abnormality determination of the trench isolation portions 20 of the chip regions 310 and 320. After that, by dividing into chip units along the scribe region 300, a semiconductor device including the region shown in FIG. 1 is formed.

As described above, in the contact electrode 81, the first minimum width L1 of the portion connected to the support substrate 11 is wider than the second minimum width L2 of the portion located in the active layer 13. Therefore, compared with a case where the first minimum width L1 and the second minimum width L2 of the contact electrode 81 are equal to each other, the contact area between the contact electrode 81 and the support substrate 11 can be increased and the noise of the support substrate 11 can be easily extracted.

Further, in the support substrate 11, the exuding layer 14 is formed at the portion in contact with the contact electrode 81. Therefore, the contact resistance between the contact electrode 81 and the support substrate 11 can be reduced, and noise can be more easily extracted from the support substrate 11.

Further, in the present embodiment, the contact electrode 81 is independently connected to the inspection device 400. Therefore, when performing the abnormality determination of the trench isolation portions 20 in the chip regions 310 and 320 in the wafer state, an erroneous determination can be prevented.

### Second Embodiment

A second embodiment will be described. In the present embodiment, the shape of the contact electrode 81 is changed from that of the first embodiment. The remaining configuration is similar to that according to the first embodiment and will thus not be described repeatedly.

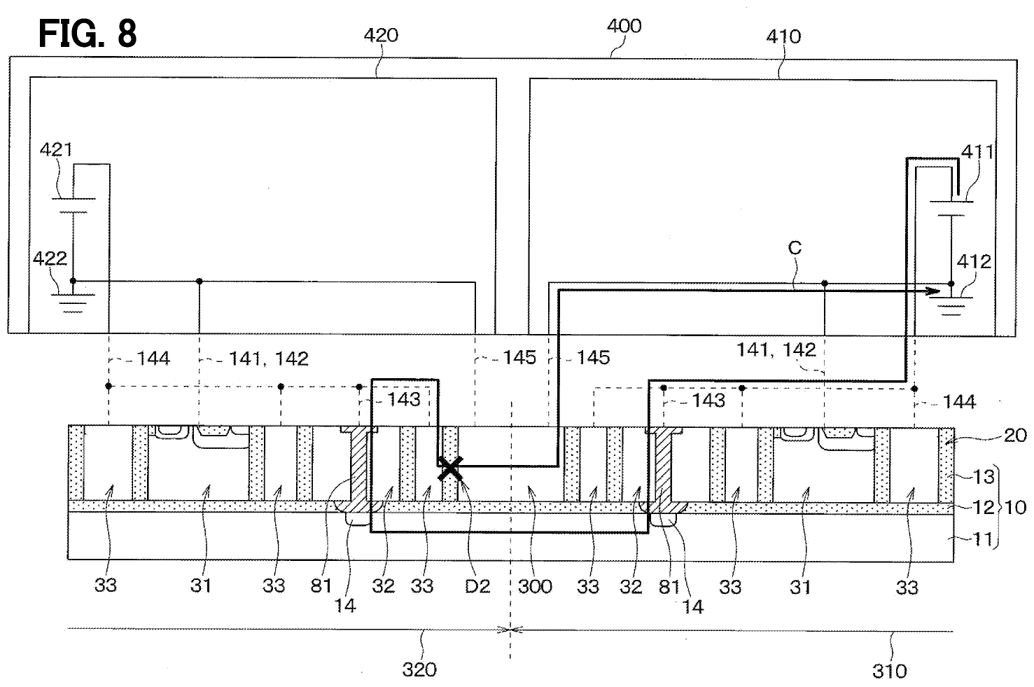

In the present embodiment, as shown in FIG. 9, the active layer 13 is divided into a first element region 31a, a second element region 31b, an extracting region 32, and a field region 33 by trench isolation portions 20.

In the first element region 31a, the MOSFET element having the body region 41, the source region 42, the drift region 43, and the drain region 44 described in the first embodiment is formed.

In the second element region 31b, an N-channel MOSFET element is formed in the present embodiment. Specifically, a P-type well layer 151 is formed in a surface layer portion of the active layer 13. In surface layer portions of the well layer 151, an N-type source region 152 and a drain region 153 are formed separately from each other. Above the main surface 10a in the second element region 31b, a gate electrode 155 is disposed through a gate insulating film 154 in a portion between the source region 152 and the drain region 153.

Further, in the second element region 31b, a silicide layer 157 is formed on the source region 152, and a silicide layer 158 is formed on the drain region 153. Each of the silicide layers 157, 158 is made of, for example, cobalt silicon (CoSi), like the silicide layers 71 and 72.

The interlayer insulating film 120 and the surface insulating film 110 have a sixth contact hole 126 that exposes the silicide layer 157 on the source region 152 and a seventh contact hole 127 that exposes the silicide layer 158 on the drain region 153. The sixth and seventh contact holes 126 and 127 are filled with tungsten, thereby forming sixth and seventh connecting vias 136 and 137 electrically connected to the silicide layers 157 and 158, respectively. Further, on the interlayer insulating film 120, sixth and seventh wiring portions 146 and 147 connected to the sixth and seventh connecting vias 136 and 137 are formed.

In the present embodiment, the MOSFET element formed in the second element region 31b has a longer switching control interval than the MOSFET element formed in the first element region 31a, and is used, for example, as a part of a circuit that generates a constant voltage. Therefore, it is desired that this MOSFET element is less likely to generate noise, and is controllable with high accuracy. That is, in the present embodiment, it can be said that a high-precision element for which high-precision control is desired is formed in the second element region 31b.

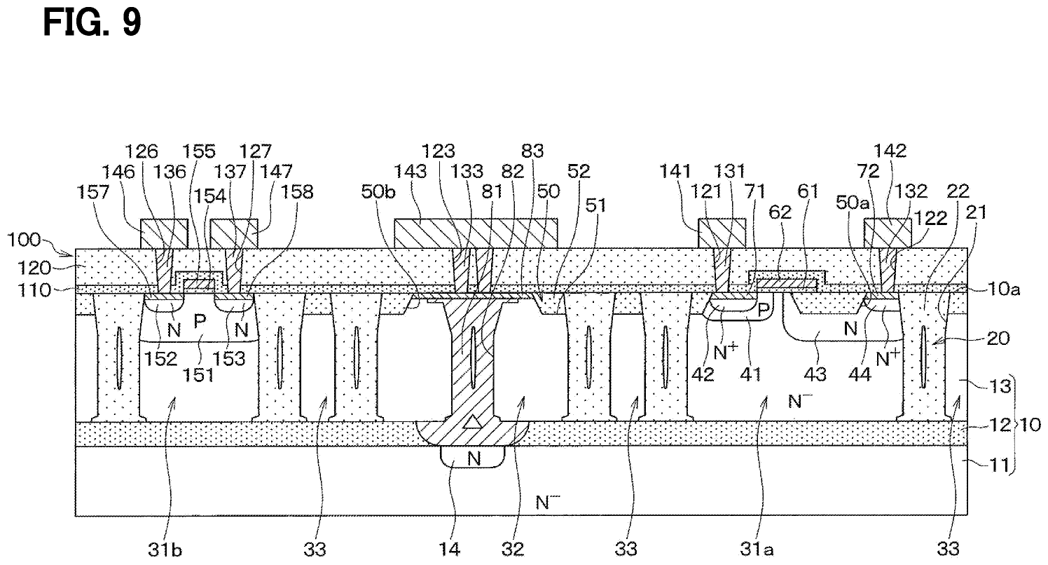

As shown in FIGS. 9 and 10, the field region 33 and the extracting region 32 are formed so as to surround the first element region 31a. In the extracting region 32, a contact electrode 81 is disposed so as to surround the element region 31. The configuration of the contact electrode 81 is the same as the configuration of the contact electrode 81 described in the first embodiment. Although FIG. 10 is a plan view, the contact electrode 81 is hatched for easy understanding.

As described above, in the present embodiment, the contact electrode 81 is formed so as to surround the first element region 31a. That is, the contact electrode 81 is formed so as to surround the noise generating element. Therefore, even if noise generated in the first element region 31a is propagated to the support substrate 11, the noise can be easily extracted from the contact electrode 81 before the noise is propagated from the support substrate 11 to the second element region 31b. Therefore, the propagation of noise to the second element region 31b can be restricted. That is, the propagation of noise to the high-precision element can be restricted.

### Third Embodiment

A third embodiment will be described. In the embodiment, the contact electrodes 81 are provided twice as compared with the second embodiment. The remaining configuration is similar to that according to the first embodiment and will thus not be described repeatedly.

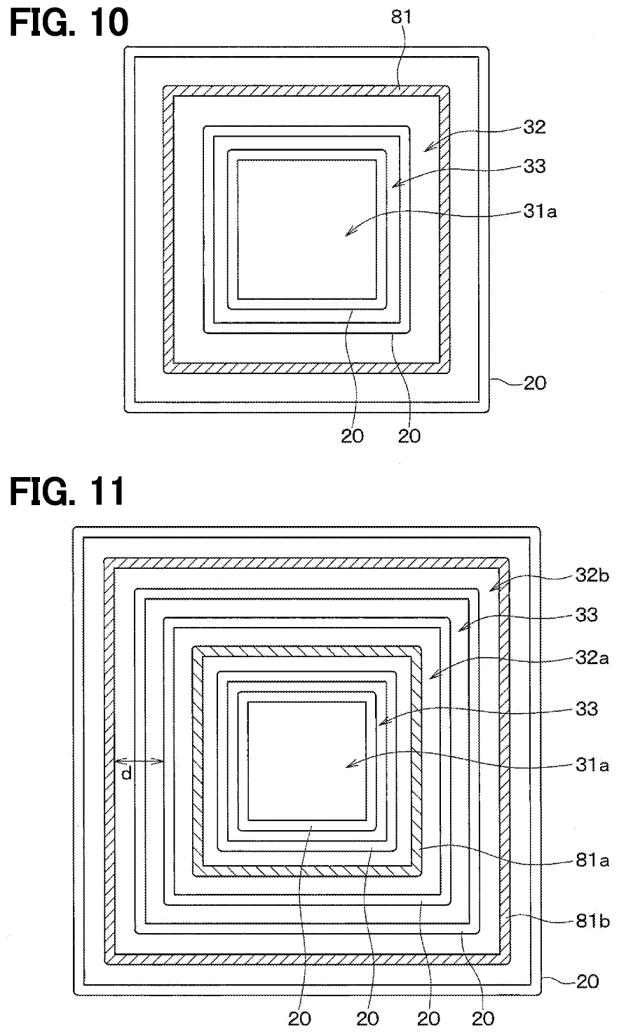

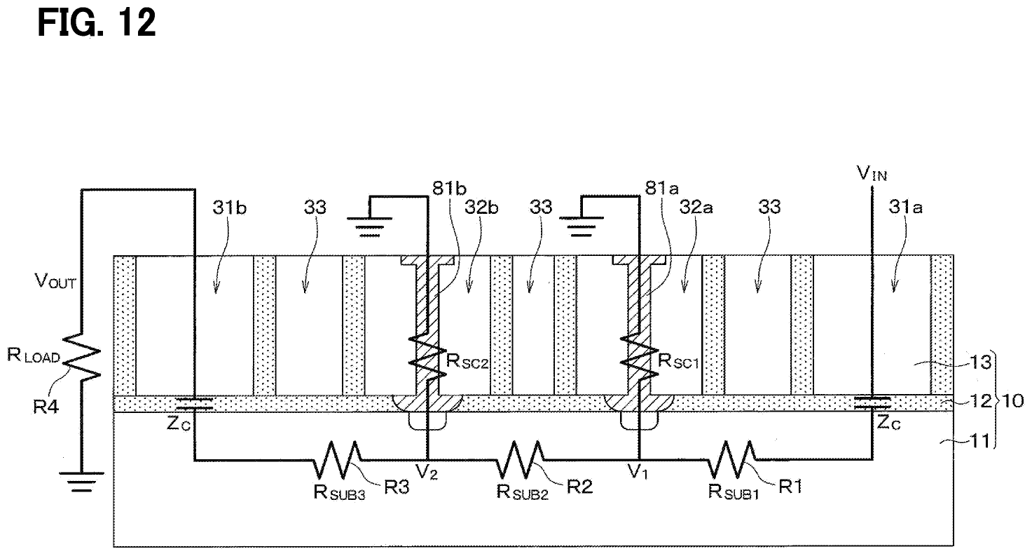

In the present embodiment, as shown in FIG. 11, a first extracting region 32a and a second extracting region 32b are partitioned by the trench isolation portions 20 so as to surround the first element region 31a. In the first extracting region 32a and the second extracting region 32b, a first contact electrode 81a and a second contact electrode 81b are respectively formed so as to surround the first element region 31a.

In the present embodiment, the first contact electrode 81a and the second contact electrode 81b are formed in the order of the first contact electrode 81a and the second contact electrode 81b from the element region 31 side. The configurations of the first contact electrode 81a and the second contact electrode 81b are the same as the configuration of the contact electrode 81 described in the first embodiment. Although FIG. 11 is a plan view, the first contact electrode 81a and the second contact electrode 81b are hatched for easy understanding.

As described above, in the present embodiment, since the first contact electrode 81a and the second contact electrode 81b are formed so as to surround the first element region 31a, noise generated in the first element region 31a can be further restricted from being propagated to the element region 31b.

The following will describe noise that can be propagated to the second element region 31b in a case where the first contact electrode 81a and the second contact electrode 81b are formed between the first element region 31a and the second element region 31b. Hereinafter, a voltage V_{OUT} output from the second element region 31b when the voltage V_{IN} is input to the first element region 31a will be described. In other words, noise of the voltage V_{OUT} propagated to the second element region 31b when noise of the voltage V_{IN} is generated in the first element region 31a will be described.

In the following, the resistance value of the first contact electrode 81a is defined as R_{SC1}, and the resistance value of the second contact electrode 81b is defined as R_{SC2}. In addition, a resistance value of a first resistor R1 between a portion of the support substrate 11 facing the first element region 31a and a portion of the support substrate 11 facing the first contact electrode 81a is defined as R_{SUB1}, and a resistance value of a second resistor R2 between the portion of the support substrate 11 facing the first contact electrode 81a and a portion of the support substrate 11 facing the second contact electrode 81b is defined as R_{SUB2}. Similarly, a resistance value of a third resistor R3 between the portion of the support substrate 11 facing the second contact electrode 81b and a portion of the support substrate 11 facing the second element region 31b is defined as R_{SUB3}.

That is, a resistance value of a noise path in the support substrate 11 from the first element region 31a to the first contact electrode 81a is defined as R_{SUB1}. Similarly, a resistance value of the noise path in the support substrate 11 from the portion facing the first contact electrode 81a to the second contact electrode 81b is defined as R_{SUB2}. Further, the resistance value of the noise path in the support substrate 11 from the portion facing the second contact electrode 81b to the second element region 31b is defined as R_{SUB3}.

Then, the impedance in the buried insulating film 12 is defined as Z_{C}. The second element region 31b is connected to the ground through a fourth resistor R4 having a resistance value R_{LOAD}.

In this case, since the contact electrode 81 is made of doped-polysilicon, it can be assumed that R_{SC1}, RS_{C2}<<R_{SUB1}, R_{SUB2}, R_{SUB3}. Further, since the buried insulating film 12 is formed thick, it can be assumed that Z_{C}<<R_{SUB1}, R_{SUB2}, R_{SUB3}.

Therefore, the voltage V₁ of the portion of the support substrate 11 facing the first contact electrode 81a, the voltage V₂ of the portion of the support substrate 11 facing the second contact electrode 81b, and the voltage V_{OUT} propagated to the second element region 31b can be expressed as follows.

$$\begin{matrix}{V}_{1} = \frac{{R}_{SC 1}}{{R}_{SUB 1} + {R}_{SC 1}} {V}_{IN} & [ Mathematical Expression 1 ] \\ {V}_{2} = \frac{{R}_{SC 2}}{{R}_{SUB 2} + {R}_{SC 2}} {V}_{1} & [ Mathematical Expression 2 ] \\ {V}_{OUT} = \frac{{R}_{LOAD}}{{R}_{SUB 3} + {R}_{LOAD}} {V}_{2} & [ Mathematical Expression 3 ]\end{matrix}$$

When Mathematical Expressions 1 to 3 are summarized, V_{OUT} is expressed as follows.

$${V}_{OUT} = \frac{{R}_{LOAD}}{{R}_{SUB 3} + {R}_{LOAD}} \times \frac{{R}_{SC 2}}{{R}_{SUB 2} + {R}_{SC 2}} \times \frac{{R}_{SC 1}}{{R}_{SUB 1} + {R}_{SC 1}} {V}_{IN} \qquad [ Mathematical Expression 4 ]$$

Here, assuming that the resistance value of the second resistor R2 in a case where the distance between the first contact electrode 81a and the second contact electrode 81b is widened is defined as R_{SUB2a}, V_{OUT1} is expressed as follows.

$${V}_{OUT 1} = \frac{{R}_{LOAD}}{{R}_{SUB 3} + {R}_{LOAD}} \times \frac{{R}_{SC 2}}{{R}_{SUB 2 a} + {R}_{SC 2}} \times \frac{{R}_{SC 1}}{{R}_{SUB 1} + {R}_{SC 1}} {V}_{IN} < {V}_{OUT} \qquad [ Mathematical Expression 5 ]$$

In this case, since the resistance value of the support substrate 11 in the case where the distance between the first contact electrode 81a and the second contact electrode 81b is widened is R_{SUB2a}, R_{SUB2}<R_{SUB2a}. Therefore, it is confirmed that when the distance between the first contact electrode 81a and the second contact electrode 81b is widened, the value of the second term in Mathematical Expression 5 becomes smaller, so that V_{OUT1} becomes smaller than V_{OUT}. That is, it is confirmed that the noise propagated in the second element region 31b can be reduced by widening the distance between the first contact electrode 81a and the second contact electrode 81b.

In a case where the second contact electrode 81b is not formed, assuming that R_{SC2} in Mathematical Expression 5 is R_{SC2a}, the result is as follows.

$${V}_{OUT 2} = \frac{{R}_{LOAD}}{{R}_{SUB 3} + {R}_{LOAD}} \times \frac{{R}_{SC 2 a}}{{R}_{SUB 2} + {R}_{SC 2 a}} \times \frac{{R}_{SC 1}}{{R}_{SUB 1} + {R}_{SC 1}} {V}_{IN} > {V}_{OUT} \qquad [ Mathematical Expression 6 ]$$

In this case, since R_{SC2}<R_{SC2a}=∞ can be defined, the second term becomes larger than the second term of Mathematical Expression 5. Therefore, in the case where the second contact electrode 81b is not formed, V_{OUT2} becomes larger than V_{OUT}. That is, in the case where the second contact electrode 81b is not formed, the noise generated in the first element region 31a is more likely to be propagated to the second element region 31b than the case where the second contact electrode 81b is formed.

As described above, V_{OUT1} can be reduced by increasing the distance between the first contact electrode 81a and the second contact electrode 81b. That is, the noise propagated to the second element region 31b can be reduced. However, as can be understood from Mathematical Expression 5, even if the interval is widened and R_{SUB2a} is increased, the second term is saturated at a certain interval, so that the value of V_{OUT1} is also difficult to decrease. That is, the amount of noise propagation is saturated.

On the other hand, when the distance between the first contact electrode 81a and the second contact electrode 81b is increased, the second contact electrode 81b becomes large as a whole. That is, when viewed from the normal direction with respect to the main surface 10a, a contact area between the second contact electrode 81b and the support substrate 11 increases with the increase in the distance between the first contact electrode 81a and the second contact electrode 81b. Therefore, the size of the semiconductor device tends to be large.

Here, it is assumed that (the reciprocal of the noise propagation amount)/(the area of the second contact electrode) is the area efficiency, and the distance between the first contact electrode 81a and the second contact electrode 81b is continuously widened. In this case, the reciprocal of the noise propagation amount saturates at a certain value, while the area of the second contact electrode 81b continues to increase. The noise propagation amount is V_{OUT1} represented by Mathematical Expression 5.

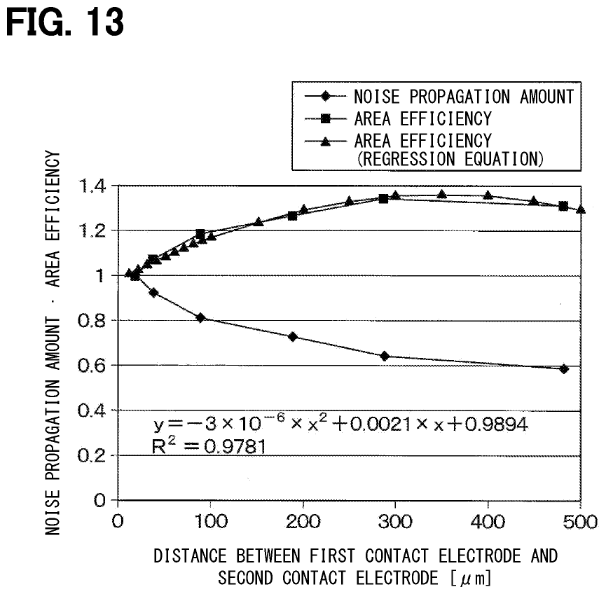

For example, when the resistivity of the support substrate 11 is 40 Ω·cm, as shown in FIG. 13, the area efficiency starts to decrease when the distance between the first contact electrode 81a and the second contact electrode 81b becomes 300 μm or more. Therefore, when the resistivity of the support substrate 11 is 40 Ω·cm, it is preferable that the distance between the first contact electrode 81a and the second contact electrode 81b is about 300 μm.

As shown in FIG. 13, a regression equation of the area efficiency is expressed by y=−3×10⁻⁶×x²+0.021×x+0.9894, where y is the area efficiency and x is the distance between the first contact electrode 81a and the second contact electrode 81b. The contribution rate is R²=0.9781.

Therefore, the distance between the first contact electrode 81a and the second contact electrode 81b is preferably close to a value at which the area efficiency becomes the maximum based on the resistance value of the support substrate 11.

### Other Embodiments

Although the present disclosure has been described in accordance with the embodiments, it is understood that the present disclosure is not limited to such embodiments or structures. The present disclosure encompasses various modifications and variations within the scope of equivalents. Furthermore, various combinations and aspects, and other combination and aspect including only one element, more than one element or less than one element, are also within the sprit and scope of the present disclosure.

For example, in the first embodiment, a P-channel-type MOSFET element may be formed in the element region 31. Similarly, in the third embodiment, a P-channel-type MOSFET element may be formed in the first element region 31a, or a P-channel-type MOSFET element may be formed in the second element region 31b.

The abnormality determination of the trench isolation portions 20 described in the first embodiment can also be applied to a case where the width of the contact electrode 81 is constant. The abnormality determination of the trench isolation portions 20 may also be performed by using an inspection device 400 having only the first inspection unit 410 and connecting the inspection device 400 to each of the chip regions in order. The abnormality determination of the trench isolation portions 20 may also be performed by using an inspection device 400 having a plurality of inspection units, and connecting each of the inspection units to each of the chip regions in order.

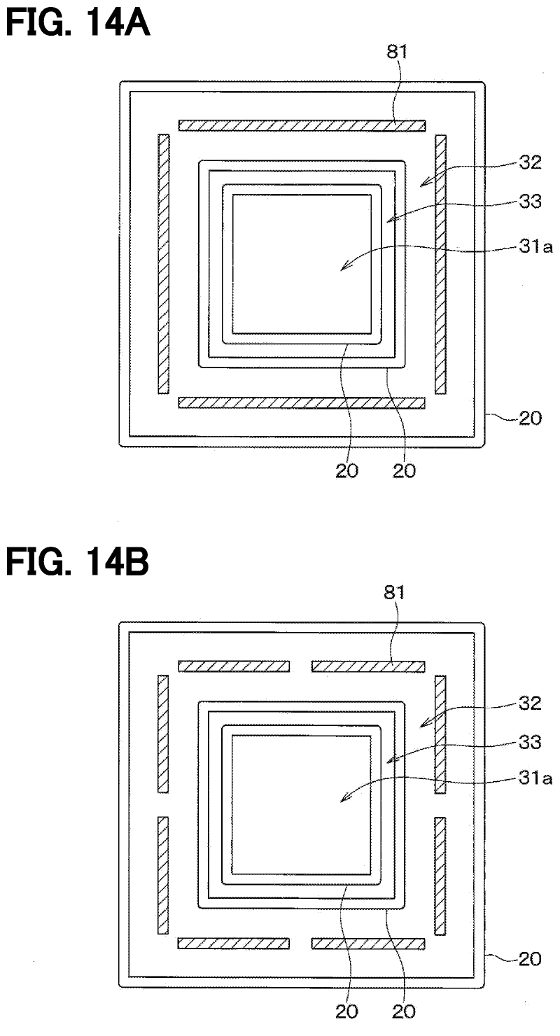

In the second embodiment, the contact electrode 81 may not be formed so as to completely surround the element region 31. For example, as shown in FIGS. 14A and 14B, the contact electrode 81 is partially divided and does not have to be completely enclosed. That is, the contact electrode 81 may be formed so as to surround the element region 31.

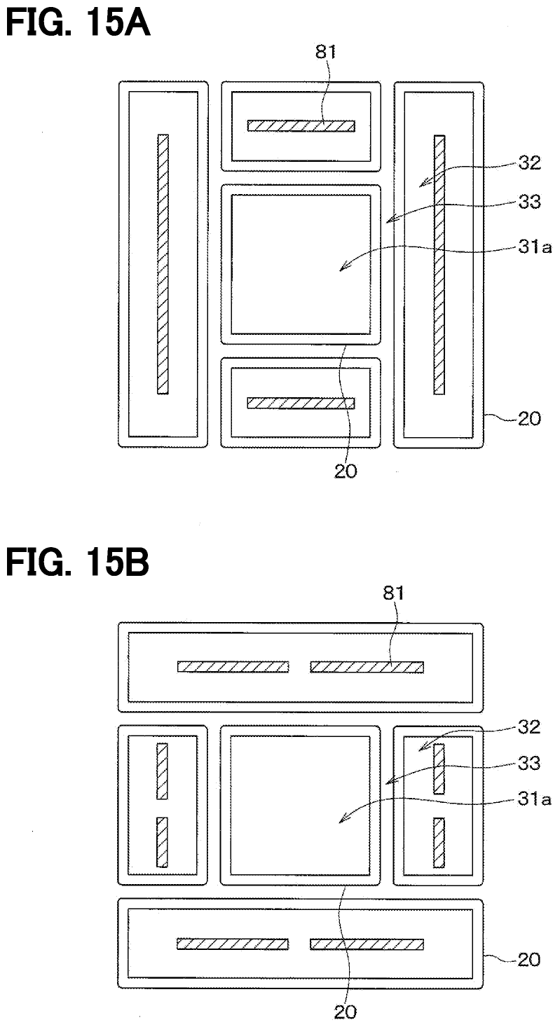

In this case, as shown in FIG. 15A, the trench isolation portions 20 may be formed so as to surround the contact electrodes 81, respectively. That is, the trench isolation portions 20 may be formed so that one trench isolation portion 20 surrounds one contact electrode 81. As shown in FIG. 15B, the trench isolation portions 20 may also be formed so that one trench isolation portion 20 surrounds two contact electrodes 81. Although not particularly shown, the trench isolation portions 20 may also be formed so that one trench isolation portion 20 surrounds three or more contact electrodes 81.

In such a configuration, the field region 33 is not divided by the trench isolation portions 20. That is, the field regions 33 are connected to each other. Therefore, for example, when the abnormality determination of the trench isolation portions 20 is performed, it is not necessary to dispose wiring or the like in each of the field regions 33, which simplifies the layout work, the inspection design, and the inspection process.

In the second embodiment, in a case where the switching elements as noise generating elements are disposed next to each other, the contact electrode 81 may be formed so as to collectively surround the element regions 31 in which the switching elements are respectively formed. For example, when two switch elements as noise generating elements are formed in the adjacent first element regions 31a, the contact electrode 81 may be formed so as to surround the two first element regions 31a. Similarly, in the third embodiment, the first contact electrode 81a and the second contact electrode 81b may be formed so as to surround the two first element regions 31a.

In the second embodiment, the contact electrode 81 may be formed so as to surround the second element region 31b. Even with such a configuration, the noise generated in the first element region 31a is less likely to be propagated to the second element region 31b, so that the same effect as that of the second embodiment can be obtained. That is, as long as it becomes difficult for the noise generated from the noise generating element to be propagated to the high-precision element, the contact electrode 81 may surround either the first element region 31a or the second element region 31b. Two contact electrodes 81 may be formed, one may be formed so as to surround the first element region 31a, and the other may be formed so as to surround the second element region 31b.

In the third embodiment, since it is preferable that the distance between the first contact electrode 81a and the second contact electrode 81b is about 300 μm, another element may be formed in a region between the first contact electrode 81a and the second contact electrode 81b. When another element is formed in the region between the first contact electrode 81a and the second contact electrode 81b, it is preferable to form an element that is less affected by noise, such as an element that executes digital processing, for example.

Further, in each of the above embodiments, the exuding layer 14 may be formed by a heat treatment different from the heat treatment for forming the source region 42 and the drain region 44 in the element region 31.

Further, in each of the above embodiments, only one third contact hole 123 may be formed, and the third wiring portion 143 may be connected to one third connecting via 133.

In each of the above embodiments, the contact electrode 81 may be made of P-type polysilicon doped with boron or the like. In this case, it is preferable that the support substrate 11 is P-type.

Further, in each of the above embodiments, the SOI substrate may be prepared in a state divided into chip unit in advance.

What is claimed is:

1. A semiconductor device comprising:
a semiconductor substrate including a support substrate, a buried insulating film, and an active layer stacked in a stated order, and having a main surface that includes a surface of the active layer opposite from the buried insulating film;
a trench isolation portion disposed in the active layer and dividing the active layer into a plurality of regions including an extracting region; and
a contact electrode disposed in a through hole that is provided from the main surface of the semiconductor substrate to reach the support substrate in the extracting region, the contact electrode electrically connected to the support substrate, wherein
in one direction along a planar direction of the semiconductor substrate, a minimum width of a portion of the contact electrode being in contact with the support substrate is wider than a minimum width of a portion of the contact electrode located in the active layer, and a width of a portion of the contact electrode located adjacent to the main surface of the semiconductor substrate is wider than the minimum width of the portion of the contact electrode located in the active layer.

2. The semiconductor device according to claim 1, further comprising
an exuding layer disposed in a portion of the support substrate being in contact with the contact electrode, wherein
the contact electrode is made of doped-polysilicon doped with a first or second conductivity-type impurity, and
the exuding layer has a conductivity-type same as the contact electrode.

3. The semiconductor device according to claim 1, further comprising
a switching element, wherein
the plurality of regions of the active layer divided by the trench isolation portion further includes an element region,
the switching element is formed in the element region, and
the contact electrode surrounds the element region.

4. The semiconductor device according to claim 3, wherein
the contact electrode includes a first contact electrode and a second electrode,
the first contact electrode surrounds the element region, and
the second contact electrode surrounds the first contact electrode.

5. The semiconductor device according to claim 3, wherein
the switching element includes a diffusion region, and
the support substrate has an oxygen concentration of 1.27×10¹⁸ atoms/cm³ to 1.69×10¹⁸ atoms/cm³.

6. The semiconductor device according to claim 1, further comprising
a wiring layer disposed on the main surface of the semiconductor substrate and including a wiring portion connected only to the contact electrode.

7. A manufacturing method of a semiconductor device comprising:
preparing a semiconductor substrate in which a support substrate, a buried insulating film, and an active layer are stacked in a stated order, the semiconductor substrate having a main surface that includes a surface of the active layer opposite from the buried insulating film;
forming a groove in the active layer to divide the active layer into a plurality of regions including an extracting region, and forming a through hole penetrating the active layer to reach the buried insulating film in the extracting region;
disposing an insulating film in the groove and the through hole to form a trench isolation portion configured by the insulating film disposed in the groove;
exposing the support substrate from the through hole by removing the insulating film disposed in the through hole, removing the buried insulating film exposed from the though hole, and deepening the through hole; and
forming a contact electrode electrically connected to the support substrate in the through hole, wherein
the exposing of the support substrate includes isotropically removing the buried insulating film by wet etching so that, in a distance between opposite sidewalls of the through hole, a minimum distance of a portion of the through hole exposing the support substrate is wider than a minimum distance of a portion of the through hole located in the active layer, and
the forming of the contact electrode includes forming the contact electrode so that a minimum width of a portion of the contact electrode being in contact with the support substrate is wider than a minimum width of a portion of the contact electrode located in the active layer, and a width of a portion of the contact electrode located adjacent to the main surface of the semiconductor substrate is wider than the minimum width of the portion of the contact electrode located in the active layer.

8. The manufacturing method according to claim 7, wherein
the forming of the contact electrode includes disposing a dope-polysilicon doped with a first or second conductivity-type impurity in the through hole,
the manufacturing method further comprising, by performing a heat treatment after the forming of the contact electrode, exuding the first or second conductivity-type impurity doped in the doped-polysilicon to the semiconductor substrate to form an exuding layer having a conductivity type same as the contact electrode at a portion of the semiconductor substrate being in contact with the contact electrode.

9. The manufacturing method according to claim 8, wherein
the forming of the groove includes forming the groove to divide the active layer into the plurality of regions including the extracting region and an element region, and
the performing of the heat treatment for forming the exuding layer further forms a diffusion region in the element region.

10. The manufacturing method according to claim 9, wherein
the preparing of the semiconductor substrate includes preparing the semiconductor substrate in which an oxygen content of the support substrate is 1.27×10¹⁸ atoms/cm³ to 1.69×10¹⁸ atoms/cm³.

11. The manufacturing method according to claim 7, further comprising:
forming a wiring layer on the main surface of the semiconductor substrate after the forming of the contact electrode; and
performing an abnormality determination of a trench isolation portion, wherein
the preparing of the semiconductor substrate includes preparing the semiconductor substrate in a wafer state in which a scribed region is arranged between a plurality of chip regions,
the forming of the wiring layer includes forming a wiring portion connected only to the electrode,
the performing of the abnormality determination includes connecting an each of the chip regions with an inspection device and determining whether an electric current flows through a path including the active layer, and
the connecting with the inspection device includes independently connecting the wiring portion with the inspection device.
